(19) United States
(12) Patent Application Publication
(10) Pub. No.: US 2010/0041327 A1
(43) Pub. Date: Feb. 18, 2010

(54) APPARATUS, SYSTEM AND METHOD FOR AIR CONDITIONING USING FANS LOCATED UNDER FLOORING

(75) Inventor: Joerg Desler, Frederick, MD (US)

Correspondence Address: VENABLE LLP, P.O. BOX 34385, WASHINGTON, DC, 20043-9998, US

(73) Assignee: Stulz Air Technology Systems, Inc., Frederick, MD (US)

(21) Appl. No.: 12/479,125

(22) Filed: Jun. 5, 2009

Related U.S. Application Data
(63) Continuation-in-part of application No. 11/966,660, filed on Dec. 28, 2007.
(60) Provisional application No. 60/877,646, filed on Dec. 29, 2006.
(60) Provisional application No. 61/129,131, filed on Jun. 5, 2008.

(51) Int. Cl. H05K 5/02

(52) U.S. Cl. 454/184

(57) ABSTRACT

An air handling unit for a computer room having a floor can include a cabinet having an upper chamber and a lower chamber separated by a partition. The lower chamber can be positioned in an air plenum located under the floor. The air handling unit can include a cooling device located in the upper chamber. A first fan assembly can include a first fan and a first mounting device coupling the first fan to the cabinet. The first fan assembly can be movable along a first axis between the upper and lower chambers. According to another embodiment, the air handling can further include a first sensor that detects air pressure in the cabinet, a second sensor that detects air pressure outside the cabinet, and a control unit that increases rotational speed of the fan when the air pressure in the cabinet is lower than the air pressure outside the cabinet.

### CROSS-REFERENCE TO RELATED APPLICATIONS

The present application claims the benefit under 35 U.S.C. §119(e) of U.S. Provisional Patent Application No. 61/129,131, filed on Jun. 5, 2008. The present application is also a continuation-in-part of U.S. patent application Ser. No. 11/966,660, filed on Dec. 28, 2007, which in turn claims the benefit under 35 U.S.C. §119(e) of U.S. Provisional Patent Application No. 60/877,646, filed on Dec. 29, 2006. The contents of the foregoing applications are expressly incorporated herein by reference in their entireties.

### BACKGROUND OF THE INVENTION

1. Field of the Invention

The present application relates generally to air conditioning systems and more particularly to floor mounted, computer room/data center air conditioning systems.

2. Related Art

Computer room data centers are often constructed with a raised floor and are equipped with, among other environmental subsystems, air conditioning systems. Raised floor air conditioning systems have certain shortcomings. The present invention aims to overcome shortcomings of conventional computer room/data center air conditioning systems.

### SUMMARY

According to an exemplary embodiment, an air handling unit for a computer room having a floor can include a cabinet having an upper chamber and a lower chamber separated by a partition. The lower chamber can be positioned in an air plenum located under the floor. The air handling unit can further include a cooling device located in the upper chamber, and a first fan assembly including a first fan and a first mounting device coupling the first fan to the cabinet. The first fan assembly can be movable along a first axis between the upper and lower chambers.

In another exemplary embodiment the cooling device can include a cooling coil.

In a further exemplary embodiment, the air handling unit can further include a first lifting device that can bias the first fan assembly toward the upper chamber. The first lifting device can include, for example, but not limited to, a gas shock, a coil spring and/or an elastomer, etc.

In an exemplary embodiment, the air handling unit can further include a locking device to lock the first fan assembly in the lower chamber. The locking device can include, for example, but not limited to, a screw, a cam, a bracket, and/or a quarter-turn screw, etc.

In another exemplary embodiment, the air handling unit can include, for example, a track and/or rollers coupling the first mounting device to the cabinet, wherein the first fan assembly can be movable along the first axis on the track and/or rollers between the upper and lower chambers.

In a further exemplary embodiment, the air handling unit can further include a front panel located on the cabinet, wherein when the first fan assembly can be in the upper chamber, the first fan assembly can be moveable through the front panel along a second axis that can be substantially transverse to the first axis.

According to a further exemplary embodiment, the first fan assembly may be movable along the second axis on, for example, a track and/or rollers.

In one exemplary embodiment, the air handling unit can further include a second fan assembly that can include a second fan and a second mounting device, and a first separation barrier that can be located between the first and second fans to separate the first and second fans into different fan compartments. In another exemplary embodiment, the first separation barrier can be coupled to the lower chamber of the cabinet. In a different exemplary embodiment, the first separation barrier can be coupled to the first and/or second fan assemblies.

In a further exemplary embodiment, the first and second fans can be independently moveable along the first axis.

According to another exemplary embodiment, an air handling unit for a computer room having a floor can include a cabinet having an upper chamber and a lower chamber separated by a partition. The lower chamber can be positioned in an air plenum located under the floor. The air handling unit can include a cooling device located in the upper chamber and a fan located in the lower chamber. The fan can distribute air into the under-floor air plenum. The air handling unit can further include a first sensor that detects air pressure in the cabinet, a second sensor that detects air pressure outside the cabinet, and a control unit that increases rotational speed of the fan when the air pressure in the cabinet is lower than the air pressure outside the cabinet.

In another exemplary embodiment, the second sensor can detect air pressure in the air plenum located under the raised floor.

In a further exemplary embodiment, the control unit can compare the air pressure in the air plenum to a pre-determined set point pressure, and can increase or decrease the speed of the fan to match the air pressure in the air plenum to the pre-determined set point pressure.

In one exemplary embodiment, the cooling device can be a coil. In a further exemplary embodiment, the air handling unit can further include a chilled water control valve that can provide chilled water to the coil, and an air temperature sensor can be located in the air plenum under the raised floor, wherein the control unit can control or regulate the chilled water control valve depending on the air temperature detected by the air temperature sensor to maintain a constant air temperature.

In another exemplary embodiment, the fan can be movable between the upper chamber and the lower chamber.

In a further exemplary embodiment, the air handling unit can further include a second fan that can be located in the lower chamber, and a first separation barrier that can be located between the first and second fans to separate the first and second fans into different fan compartments.

### BRIEF DESCRIPTION OF THE DRAWINGS

The foregoing and other features and advantages of the invention will be apparent from the following, more particular description of various exemplary embodiments including a preferred embodiment of the invention, as illustrated in the accompanying drawings wherein like reference numbers generally indicate identical, functionally similar, and/or structurally similar elements. The left most digits in the corresponding reference number indicate the drawing in which an element first appears.

FIG. 1 depicts an exemplary electronically commutated (EC) fan including a cut-away view of the EC fan motor according to an exemplary embodiment of the present invention;

FIG. 2 depicts an exemplary computer room air handler (CRAH) according to an exemplary embodiment of the present invention;

FIG. 3 depicts an exemplary improved computer room air handler (CRAH) including separation barriers and isolated individual compartments for each of the plurality of EC fans according to an exemplary embodiment of the present invention;

FIG. 4 depicts an exemplary A-frame coil design for comparison to various exemplary embodiments of the present invention;

FIG. 5 depicts an exemplary V-frame coil design according to an exemplary embodiment of the present invention;

FIG. 6 depicts an exemplary coil design detail for comparison to various exemplary embodiments of the present invention;

FIG. 7 depicts an exemplary chilled water/chilled water dual circuit coil design, including interlacing with fin stock according to an exemplary embodiment of the present invention;

FIG. 8A depicts an exemplary schematic illustration of an exemplary chilled water coil assembly;

FIG. 8B depicts an exemplary isometric drawing of an exemplary V-shaped chilled water coil design, according to an exemplary embodiment;

FIG. 8C depicts an exemplary embodiment of a v-shaped chilled water coil design according to an exemplary embodiment;

FIG. 9 depicts an exemplary two single circuit coil assembly;

FIG. 10 depicts a cross section view of an exemplary two single circuit coil assembly;

FIG. 11 depicts an exemplary dual circuit interlaced coil assembly;

FIG. 12 depicts a cross section view of an exemplary dual circuit interlaced coil assembly;

FIG. 13 depicts an exemplary embodiment of a computer system as may be used as part of various exemplary embodiments of the present invention;

FIG. 14 depicts an exemplary embodiment of an air handling unit for a computer room having a floor and including a fan assembly moveable along a first axis to a position in an air plenum below the floor;

FIG. 15 depicts the embodiment of FIG. 14 further including a lifting device to bias the fan assembly toward the upper chamber of the air handling unit cabinet;

FIG. 16 depicts the embodiment of FIG. 14 further including a front panel located on the air handling unit cabinet; and

FIG. 17 depicts an exemplary variation of the embodiment of FIG. 14, wherein the fan assembly is located in the upper chamber and is moveable through the front panel along a second axis that is substantially transverse to the first axis.

### DETAILED DESCRIPTION

Various exemplary embodiments of the invention including preferred embodiments are discussed in detail below. While specific exemplary embodiments are discussed, it should be understood that this is done for illustration purposes only. A person skilled in the relevant art will recognize that other components and configurations can be used without parting from the spirit and scope of the invention.

### Overview of Various Exemplary Embodiments

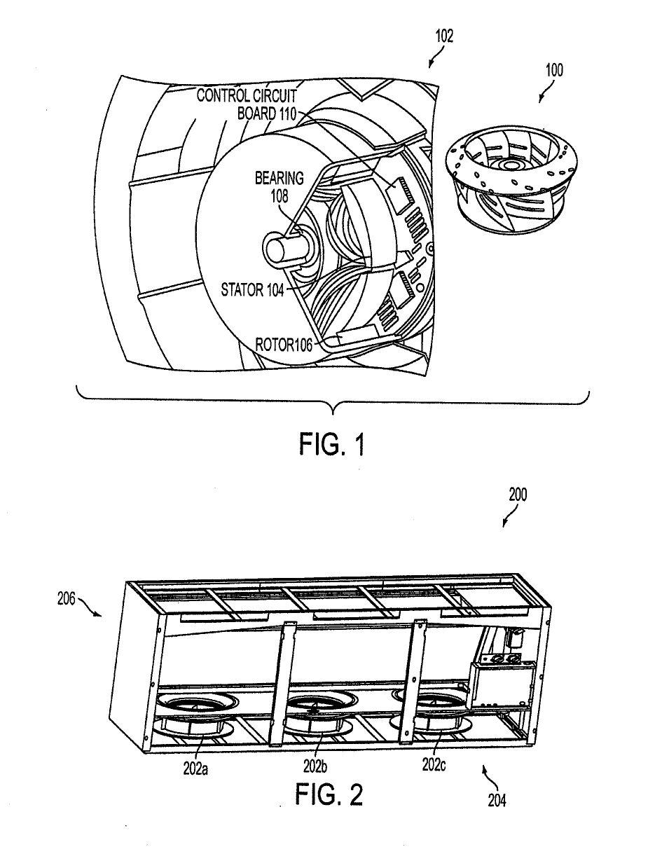

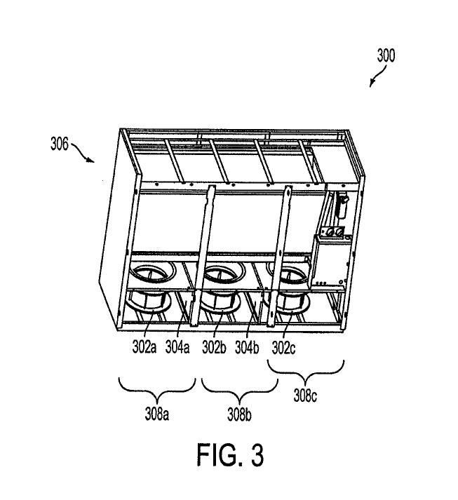

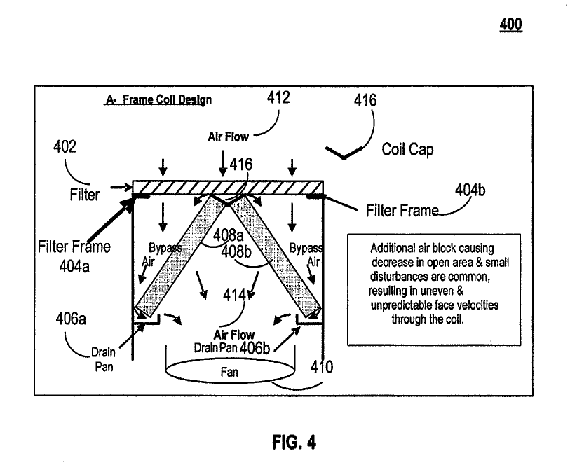

An exemplary embodiment of the present invention sets forth an apparatus, system and method of providing a high efficiency computer room air handler (CRAH) 300, as described further below with reference to FIG. 3. According to an exemplary embodiment, an exemplary CRAH system as depicted in FIG. 3 may provide, e.g., but not limited to, an exemplary cabinet adapted to provide, e.g., but not limited to, separation of, e.g., but not limited to, direct driven plug fans. In an exemplary embodiment, the fans may include, e.g., but may not be limited to, electronically commutated (EC) fans 100 as discussed further below with reference to FIG. 1.

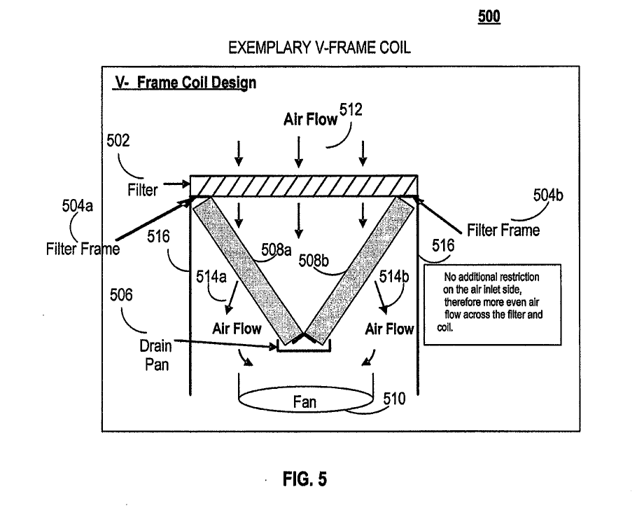

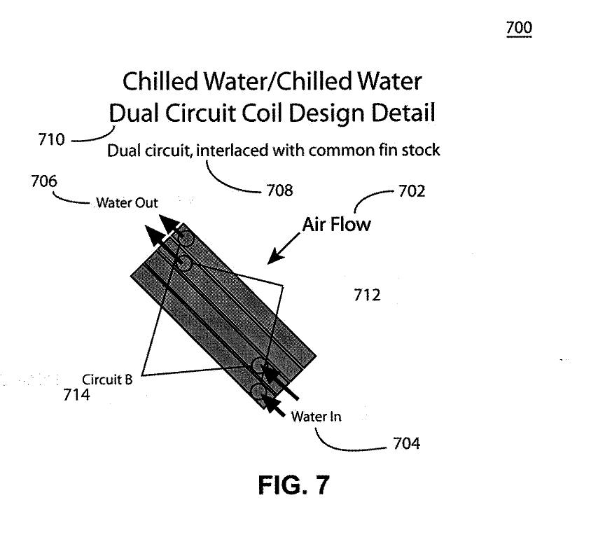

According to one exemplary embodiment, an exemplary V-shaped Chilled Water coil design may be used as discussed further below with reference to FIG. 5. In an exemplary embodiment, the V-shaped chilled water coil design 500 may be optionally accompanied by an exemplary V-shaped Dual Chilled Water exemplary interlaced coil design, as discussed further below with reference to FIG. 7.

### Exemplary Embodiment of an Electronically Commutated (EC) Fan

FIG. 1 depicts an exemplary embodiment of a fan. The fan may include, but not be limited to, for example, plug fans. In an exemplary embodiment, the plug fan is an alternating current (AC) plug fan. In another exemplary embodiment, the plug fan is an electronically commuted (EC) plug fan. While a number of the embodiments described herein refer to electronically commuted (EC) plug fan 100, it will be understood that the present embodiments may apply to any type of fan or fan related device, including corresponding methods.

Various exemplary embodiments of the present invention may include cabinets housing fans, such as for example electronically commutated (EC) fans 100, as described further below. An exemplary EC fan 100 may include, according to an exemplary embodiment, an electronically commutated permanent magnet direct current (DC) motor 102, and a plurality of fan blades (not labeled).

In one exemplary embodiment, electric motor 102, may include, e.g., but not be limited to, a stator 104, a rotor 106, a bearing 108, and/or an electronic control circuit board 110. EC motor 102 technology, according to an exemplary embodiment, may be insensitive to voltage fluctuations, may run extremely quietly, and may have continuously adjustable speeds and may include reduced power consumption, as compared to other fan technologies. In essence, according to an exemplary embodiment, the EC fan motor 102 may include, e.g., but may not be limited to, a direct current (DC) motor with shunt characteristics. The rotary motion of the exemplary motor 102 may be achieved by supplying power via a switching device (i.e., a commutator). In other motors, the commutator may include brushes, having a much shorter and limited service life of only a few thousand hours, as compared to an EC fan motor. With EC fan motor 102, according to an exemplary embodiment, commutation may be performed using solid state electronics (including, e.g., but not limited to, control circuit board 110) and may therefore be inherently wear-free by design.

According to an exemplary embodiment, EC fan 100 may include an EC fan available from ebm-papst Inc. of 100 Hyde Road, Farmington, Conn. 06034. Unlike alternating current (AC) fans, EC fans 100, according to an exemplary embodiment, may include an electronically commutated permanent magnet DC motor 102. This EC permanent magnet technology is insensitive to voltage fluctuations, may provide for extremely quiet operation and long life and may enable continuously adjustable fan speeds. EC motors 102 may help to minimize operating costs with high efficiencies of up to 92%, according to an exemplary embodiment.

Exemplary EC fans 100 from ebm-papst may comply with the strictest EMC standards including, e.g., but not limited to: emissions EN50081-1, interference immunity, EN61000-6-4 and harmonic, and current emissions EN61000-3-2.

Furthermore, the exemplary EC fans may have been granted all important international approvals in accordance with Verband der Elektrotechnik, Elektronik und Informationstechnik (VDE) (the German certification mark of the VDE Association for Electrical, Electronic & Information Technologies), Underwriters' Laboratory (UL), Canadian Standards Association (CSA), China Compulsory Certification (CCC) and the Russian state standard Gosudarstvennyy Standart (GOST) (Russian:Γocy [symbol] apcTBeHHbI [symbol] cTaH [symbol] apT).

Computer Room Air Handler (CRAH)

FIG. 2 depicts an exemplary diagram illustrating an exemplary computer room air handler (CRAH) 200 for comparison to a CRAH 300 depicted in FIG. 3, according to an exemplary embodiment of the present invention. FIG. 2 depicts a computer room air handler (CRAH) 200, including an exemplary floor mounted, air conditioner.

Also, in CRAH 200, as shown, exemplary fans 202 may be provided. CRAH 200 includes, three exemplary fans 202a, 202b, and 202c sharing a common space 204.

CRAH 200, may include, a down-flow or an up-flow version. A down-flow version may pull air into the top of the unit, through a filter and a coil, and may discharge air at the bottom of the unit. The air typically may be discharged into a raised floor. An up-flow version may pull air into a lower front or a lower rear of the unit, through, a filter and a coil, and may discharge air at the top of the unit.

It is important to note that the CRAH 200 provides that all three fans 202 share a common space 204 (i.e., there are no barriers separating the three fans); thus all three exemplary fans share a common compartment 204 of cabinet 206. For such a configuration to work at the intended efficiency, fans 202 must conventionally be spaced quite far apart, taking a substantially large amount of floor space to provide a given unit of air handling.

Even EC fans used in a Computer Room Air Handler (CRAH) 200 operate inefficiently. For example, EC fans 202a-202c of CRAH 200 are shown performing at 17,000 scfm at 0.1″ external static pressure. In the CRAH 200, the EC fans 202 must, for example, typically operate at 100% capacity which results in energy consumption of approximately 9.0 kW, at substantially greater energy consumption than the improved CRAH 300 described further below with reference to FIG. 3, according to an exemplary embodiment.

### Exemplary Embodiment of a High Efficiency Computer Room Air Handler (CRAH)

FIG. 3 depicts an exemplary diagram 300 illustrating an exemplary improved CRAH design, including fan separation according to an exemplary embodiment of the present invention. An exemplary and non-limiting system 300 may include fan separation barriers 304a, 304b (collectively herein as 304), according to an exemplary embodiment. Improved CRAH 300 is available from the Assignee of the present invention, Stulz Air Technology Systems Inc. (Stulz-ATS) of 1572 Tilco Drive, Frederick, Md. 21704 USA. CRAH 300, according to an exemplary embodiment, may, e.g., but not be limited to, perform at 17,000 scfm at 0.5″ external static pressure. According to an exemplary embodiment, the EC Fans 302 may operate at 70% capacity which results in energy consumption of approximately 5.5 kW, as compared to other CRAHs.

An exemplary embodiment of the present invention sets forth an apparatus, system and method of providing a high efficiency computer room air handler (CRAH). According to an exemplary embodiment of the present invention, the exemplary apparatus, system and method may include a CRAH 300, which may include, e.g., but not limited to, an exemplary vertical, floor-mounted, precision air conditioner which may be used in a, e.g., but not limited to, raised-floor, computer room and/or a data center(s).

CRAH 300, in an exemplary embodiment may include a cabinet 306, including a plurality of vertically placed EC fans 302a, 302b and 302c. Resulting benefits of the CRAH according to the exemplary embodiment, may include a significant reduction in unit energy consumption, as well as, a reduction in the amount of floor space required for installation. According to an exemplary embodiment, the CRAH 300, as discussed herein, may refer to, an exemplary vertical, floor mounted, precision air conditioner as depicted in FIG. 3. In an exemplary embodiment, CRAH 300 may include a plurality of exemplary EC fan(s) 302a-302c (described further above with reference to EC fan 100 of FIG. 1). As depicted, according to an exemplary embodiment, cabinet 306 of CRAH 300 may include, e.g., but not be limited to, a plurality of EC centrifugal fans. According to an exemplary embodiment, the exemplary EC fan(s) 100 may include direct driven plug fan technology. As shown, according to an exemplary embodiment, cabinet 306 of CRAH 300 may include separation barriers 304a, 304b, which may isolate each of fans 302a, 302b, and 302c in separate compartments 308a, 308b, and 308c, respectively, formed by the separation barriers 304a, 304b and/or walls of cabinet 306, according to an exemplary embodiment.

According to an exemplary embodiment, separation barriers 304a, 304b may be constructed of a sturdy resilient material, such as, e.g., but not limited to, a metal or plastic plate. According to an exemplary embodiment, the exemplary separation barriers 304 may include, e.g., but may not be limited to, a resilient barrier, a plate, a metal plate, an aluminum plate, a steel plate, a galvanized steel plate, a plastic plate, a fireproof barrier, and/or an air interrupting barrier, etc. A barrier of any other material may also be used.

CRAH 300, according to an exemplary embodiment, can include, e.g., but not be limited to, a down-flow or an up-flow version of the CRAH. An exemplary down-flow version may pull air into the top of the unit, through a filter and a coil, and may discharge air at the bottom of the unit. The air may typically be discharged into a raised floor. An exemplary up-flow version may pull air into an exemplary lower front or an exemplary lower rear of the unit, through, e.g., but may not be limited to, a filter and a coil, and may discharge air at the top of the unit.

According to an exemplary embodiment, the EC fan 100 of FIG. 1, as described herein, may be used as one of the plurality of EC fans 302 inside the exemplary CRAH 300. According to an exemplary embodiment, EC fans 302 of various exemplary diametric dimensions may be used in the exemplary CRAH 300. In an exemplary embodiment, EC fans 302 may have a diameter ranging from, e.g., but not limited to, 400-750 mm, etc., according to various exemplary embodiments.

Separation of EC Fan Technology in Individual Compartments Yields Energy Savings

While the introduction of EC fans to precision air conditioning allows for measurable cost savings in energy usage and maintenance, quieter operation, and improved motor longevity; a truly innovative increase in EC fan efficiency may only be accomplished, when taking advantage of an exemplary embodiment of the present invention. According to an exemplary embodiment, a substantial increase in EC fan efficiency may be experienced when the air pressure drops inside the CRAH 300 to a minimal level, i.e., as low as possible, where air-flow conditions are then optimized.

FIG. 3, depicts an exemplary embodiment of CRAH 300, including a separation barrier 304a, 304b, separating each of the plurality of EC fans 302a-302c within cabinet 306 into separate compartments 308a-308c, respectively. The unique, novel and non-obvious CRAH 300 cabinet design optimizes air flow and static pressure which in turn enables the unit to require decreased energy consumption. Stulz-ATS Inc. provides a CRAH 300 according to an exemplary embodiment, which includes separation, so as to realize the lowest unit energy consumption in the industry.

Through extensive testing, Assignee Stulz-ATS found that when EC Fans 100 are placed horizontally, side by side in close proximity to each other in a CRAH 200 without barriers, the air-flow between the fans impedes the performance of the fans and actually increases air pressure drop inside the cabinet, thus decreasing performance and efficiency of the CRAH. The loss of performance and efficiency was found to nullify energy saving benefits intended by EC fan technology.

EC fan manufacturers generally recommend installing EC fans at least as far apart as their own diameter to sustain a fan's optimal efficiency. Installing fans this far apart is less practicable for a CRAH as such a distance increases the CRAH's need for floor space substantially. Thus, the CRAH 200 of FIG. 2 requires a large amount of floor space to accommodate sufficient spacing between the plurality of EC fans 202a-c in the shared compartment. As shown in FIG. 3, according to an exemplary embodiment, using Applicant's fan separation design 300, according to an exemplary embodiment, including, e.g., but not limited to, separation barriers 304a, 304b, may avoid the need for this additional floor space necessitated by fan separation, by individually separating EC fans so that the EC fans may operate without losing fan efficiency.

According to an exemplary embodiment, Applicant's method of FIG. 3 of locating and separating EC fans 302 by a separation barrier 304 may allow the benefits of the EC Fan technology to be realized even when multiple fans are mounted closer to one another than the fan manufacturers' recommendations. Applicant discovered that when EC fans are installed in close proximity to each other, the performance is substantially improved if the fans are separated with a physical separation barrier 304. Without adequate separation, it was discovered that EC fans may impede one another's performance significantly.

As depicted in the CRAH 200 of FIG. 2, without fan separation of an exemplary embodiment, EC fans 202 in a CRAH 200 must operate at 100% capacity resulting in energy consumption of 9.0 kW. On the other hand, using the fan separation method including a separation barrier of an exemplary embodiment of Applicant's invention, CRAH 300 of FIG. 3, performing at 17,000 scfm at 0.5″ external static pressure, EC fans 302 operate at 70% capacity, which results in energy consumption of only approximately 5.5 kW. Thus an energy savings of 3.5 kW may be obtained, according to one exemplary embodiment.

The unique Stulz-ATS method, according to an exemplary embodiment of the invention, of separating EC fans 302 with a barrier 304 may allow a CRAH 300 to operate with a compact cabinet 306 (i.e., a smaller footprint than other cabinets 206) at the same performance conditions as a CRAH 200, but with increased capacity and motor efficiency. The exclusive cabinet design 306 depicted in FIG. 3, according to an exemplary embodiment, may allow the most effective application of multiple EC Fans 302a-302c in a CRAH 300 by optimizing air flow and static pressure, and by allowing a CRAH 300 to realize higher energy efficiency without increasing size of the cabinet 306.

According to an exemplary embodiment, as shown in FIG. 3, separating EC fans 302 from one another with a separation barrier 304a, 304b, according to an exemplary embodiment, may provide performance advantages and energy savings, and may apply whenever more than 1 fan is installed in a CRAH 300. In a CRAH 200, with more than 1 fan 202 without barrier separations, two or more fans would be operating within the same compartment. The separation method, according to an exemplary embodiment, may ensure that each fan 302a-302c, operating inside a CRAH 300, may be in its own compartment 308a-308c of cabinet 306, with little or no air leaking into the compartments 308 of adjacent fans 302. The separation material, or barrier 304, may be constructed of any kind of material that eliminates most, or all, air leakage to compartments of adjacent fans 302. According to an exemplary embodiment, separators 304a, 304b may be constructed of a metal plate material, e.g., but not limited to, aluminum, steel, nickel, zinc, copper, etc. The barrier may be of a thickness capable of resilience. An exemplary separation barrier 304 may be constructed of steel of a thickness of 0.059″ (inches), (16 Ga.), which may in an exemplary embodiment be comparable to the thickness of the walls of the housing of the cabinet 306. According to an exemplary embodiment, an exemplary separation barrier 304 may be rectangular in shape and maybe placed equidistant between two adjacent EC fans. The separation barrier 304 may in one exemplary embodiment be part of the structure of the cabinet 306. In another exemplary embodiment, the separation barrier 304 may be separate from the cabinet, and may be installed within the cabinet and secured in place by a mounting mechanism such as, e.g., but not limited to, screws, bolts, welding, or the like. In an exemplary embodiment, the barrier 304 may be load bearing. In exemplary embodiments, differing separation distances may be used as well. For example, in an exemplary embodiment, the minimum distance between the edge of a fan and a barrier may be 2″.

Overview of Chilled Water Coil Assembly and V-Frame Coil Design

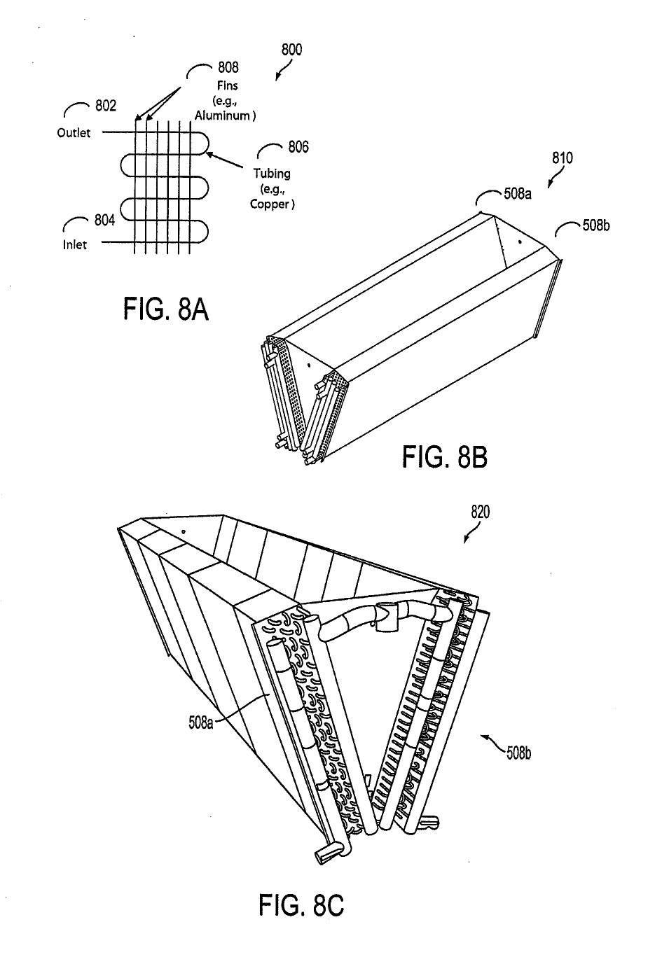

FIG. 8A depicts an exemplary chilled water coil assembly 800, including an exemplary outlet 802 (which may be used as, e.g., but not limited to, a water outlet), an exemplary inlet 804 (which may be used as, e.g., but not limited to, a water inlet), tubing 806 (which may include, e.g., but may not be limited to, copper (Cu) tubing) connecting the outlet and inlet, and fins 808 (which may include, e.g., but may not be limited to, aluminum (Al) fins). As shown, the exemplary chilled water coil 800 may include, e.g., but may not be limited to, multiple rows of the seamless, drawn tubes 806 which may be joined at the ends to form a continuous circuit.

The circuit may be designed for fluid (which may include, e.g., but may not be limited to, water and/or chilled water, etc.) to flow through the tubing, entering one end 804 and exiting the other end 802. As shown, the plurality of thin plates (which may include, e.g., but may not be limited to, Al plates) may be mechanically bonded to the tubes 806 (which may include, e.g., but may not be limited to, copper tubes). The plates may be closely arranged side by side along the length of the copper tubes 806 to form the aluminum fins 808. Spacing between fins 808 may be designed at an optimal, minimum distance that allows air to flow through the spaces between the fins 808. The assembly of copper tubes 806 and aluminum fins 808 may be held together with end plates typically, e.g., but not exclusively limited to, formed of galvanized steel.

Cooling fluid flows through the copper tubes 806 at a temperature designed to lower the surface temperature of the aluminum fins 808 below the temperature of the air to be treated. When warm air is forced through the coil assembly 800, it may pass between the aluminum fins 808, transferring heat from the air into the aluminum material. Heat from the aluminum fins 808 may then pass to the copper tubing 806 where it may be removed by the cooling fluid as it flows through the copper tubing.

An exemplary embodiment of the present invention sets forth an improved, useful, novel and non-obvious V-shaped coil 500, referred to as a “V-frame” 500, which is discussed further below with reference to FIG. 5.

According to an exemplary embodiment, the V-frame coil 500 may provide increased energy efficiency for a CRAH 200, 300 as compared to the use of an exemplary A-frame shaped coils 400 shown in FIG. 4 below. An exemplary embodiment of the V-frame 500 may include a V-shaped chilled water coil design 500 as depicted below and described further with reference to FIGS. 5, 6, and 7. According to one exemplary embodiment, an optional V-frame coil design may include a dual circuit chilled water design 700.

According to an exemplary embodiment, an optional V-frame dual circuit chilled water coil design 700 may include an interlaced coil design 708 as set forth and described with reference to FIG. 7 below. According to an exemplary embodiment, the optional V-frame dual circuit chilled water interlaced coil design 700 may be included as part of a vertical, floor-mounted, precision air conditioner to increase energy efficiency, as compared to other designs. An exemplary embodiment of the present invention, including a vertical, floor mounted, precision air conditioner, integrated with a V-frame coil design may optimize air flow and static pressure which in turn may allow the unit to realize decreased unit energy consumption, yielding the lowest unit energy consumption in the industry, to date.

A vertical, floor mounted air conditioner is referred to as a computer room air handler (CRAH) 200, 300. As noted above, according to an exemplary embodiment, CRAH 200, 300 may be a down-flow version or an up-flow version. Down-flow versions may pull air via a fan 310 into the top of the unit, through a filter 402 and a coil 408, and may discharge air at the bottom of the unit. The air may typically be discharged into a raised floor, upon which computer and/or other data center equipment, telecommunications device, power supplies and the like may be placed. Up-flow versions may pull air into the lower front or lower rear of the unit, through a filter 402 and a coil 408, and may discharge air at the top of the unit.

Exemplary A-Frame coil

FIG. 4 depicts an exemplary diagram 400 illustrating an exemplary slab A-Frame coil design 400 described for comparison purposes to an exemplary embodiment of the present invention. FIG. 4 depicts an exemplary embodiment of a A-Frame coil design 400, which may include a downward air flow 412, drawn via a fan 410. In an exemplary embodiment, air flow 412 is drawn through filter 402, which may be held in place via filter frame 404, which may impede some air flow. The A-Frame coil 408a, 408b (collectively referred to as 408) creates an A-shaped crown at a point which includes a necessary coil cap 416. Air is drawn through coil 408a, 408b yielding air flow 414. Unfortunately not all air flow 412 reaches air flow 414 by passing through coil 408. Instead, some of airflow 412 is obstructed and diverts to the area remaining between cap 416 and frame 404a and 404b. Instead of flowing through coil 408, a portion of airflow 412 bypasses the coil and leaks around the drain pans 406a and 406b as shown.

As noted above, the A-frame coil design 400 requires the necessary coil cap 416. The cap 416 of the A-frame coil design creates an air blockage, causing a decrease in open area, and making small disturbances common in airflow 412 as it flows to airflow 414. The air blocks (such as, e.g., but not limited to, coil cap 416, filter frames 404a and 404b, and drain pans 406a and 406b), may decrease the open area, and the air flow disturbances may result in uneven, unpredictable face velocities through the coil 408. Pressure drops across the drain pan 406 may increase a risk of water carry-over into the air stream 414 as it is drawn by fan 410.

A-frame coils 400 may include two (2) slab coils held together at the top so as to form an “A” shape as shown in FIG. 4. The point where the two coils 408a, 408b are joined is located directly under the center of the filter 401 media, thus impeding airflow across the most efficient area of the filters 401. Small air disturbances are common, resulting in uneven and unpredictable face velocities through the coils 408a, 408b. Also, with the A-frame coil design 400, the high pressure side of the coils 408a and 408b may be separated from the low pressure side at the bottom edges of the coil assembly, in the same area where two drain pans 406a and 406b are positioned.

Exemplary V-Coil Providing Reduced Internal Pressure Drop-Optimizes Air Flow and Decreases Energy Consumption

FIG. 5 depicts an exemplary diagram 500 illustrating an exemplary V-shaped Chilled Water coil design as may be provided, according to an exemplary embodiment of the present invention.

FIG. 8A provides a schematic illustration of an exemplary V-shaped Chilled Water coil design 810 as described above.

FIG. 8B depicts an exemplary isometric projection/view of a v-shaped chilled water coil design 810.

FIG. 8C depicts an exemplary drawing of a v-shaped chilled water coil design 810 illustrating coils and fins.

According to an exemplary embodiment, as the name indicates, an exemplary V-frame coil 500 may be formed with 2 slab coils 508a, 508b in the shape of a “V” as depicted in diagram 500. Referring to design 810 of FIG. 8, the slab coils 508a and 508b are shown in perspective view. Because a V-frame coil 508a, 508b, may be joined together at the bottom, the area directly below the filters may be left open for efficient airflow. The exemplary V-frame coil 500 may optimize air flow and pressure drop inside the cabinet 306, which may improve CRAH 300 capacity and total efficiency.

Additionally, according to an exemplary embodiment, the V-frame coil design 500 may allow the CRAH 300 to be designed with no pressure drop across the condensate drain pan 506. With a V-frame coil design 500, according to an exemplary embodiment, the high pressure side of the coil assembly may be separated from the low pressure side between the top edges of the coil assembly and the filter frame 504.

Optional Dual Chilled Water Interlaced Coil Design

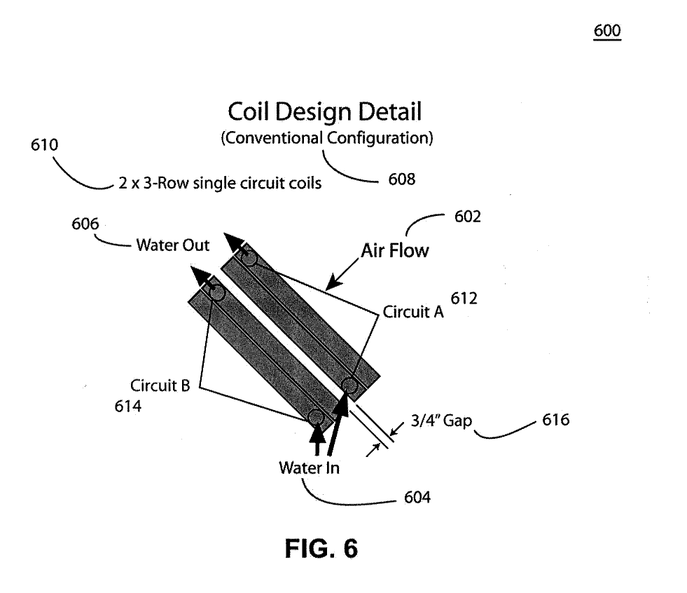

FIG. 6 depicts an exemplary diagram 600 illustrating an exemplary coil design 610, which may be modified or used for comparison to one or more exemplary embodiment. The coil design detail 600 depicted in FIG. 6 shows one side of an A or V configuration. The coil design 600 includes an exemplary 2×3-row single circuit coils 610. As depicted, water comes in one end 604 and out the other end 606, creating two circuits A 612, B 614. The coil design 600, according to an exemplary embodiment, may require at least a ¾″ gap 616 between coils to allow proper air-flow. By including the gap, overall coil size increases. Increased air side pressure drop may be experienced due to improper fin alignment. Higher fan energy is consumed to overcome additional pressure drop, according to an exemplary embodiment.

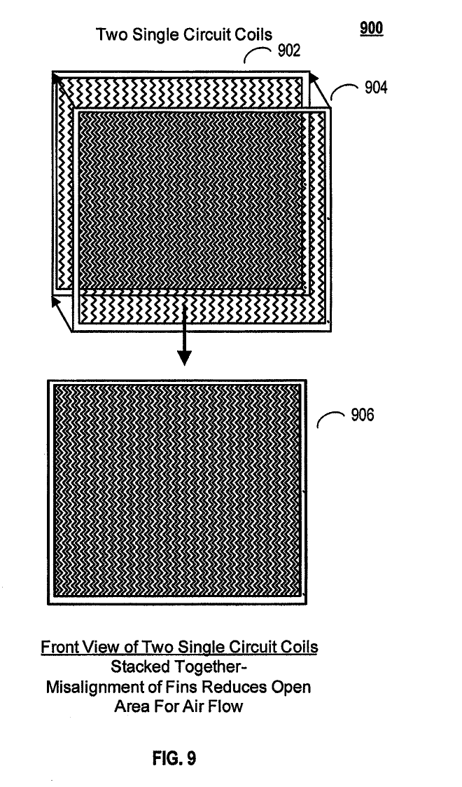

FIG. 9 depicts an exemplary two single circuit coil assembly 900, showing the coil design 600 of FIG. 6 in expansive view. As illustrated, two single circuit coils 902 and 904 are provided, which are shown in front view as combined circuit coil 906. The two single circuit coils 902, 904 are stacked together, causing misalignment of fins, and reducing the open area of air flow.

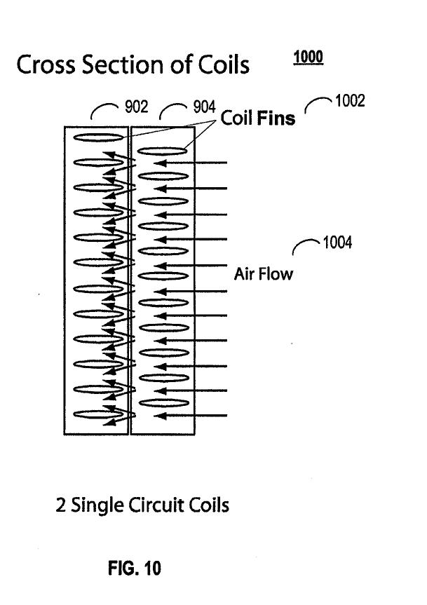

FIG. 10 depicts a cross section 1000 of the coil assembly 900, showing the respective coil fins 1002. Also shown is how air flow 1004 is conducted between the coils in the two single circuit coil assembly.

FIG. 7 depicts an exemplary diagram 700 illustrating an exemplary V-shaped Dual Chilled Water Dual Circuit Coil exemplary interlaced coil design 708 according to an exemplary embodiment of the present invention. According to an exemplary embodiment, a dual circuit, interlaced with a common fin stock may be used. As depicted, water enters one end 704 and exits another end 706. As shown in coil design 708, only one side of the v-configuration is shown. As can be seen, by comparison to design 608, no gap 616 is required. As shown, in an exemplary embodiment, Circuit A and Circuit B of dual circuit coil design 708 may be interlaced. The dual circuit coil design 700 may provide optimized heat transfer due to increased air flow resulting from eliminating restrictions caused by misaligned fins of two single coils. The design 708 can include increased capacity by ˜10% for independent circuit operation. Parallel operation, according to an exemplary embodiment, of both circuits is possible, nearly doubling capacity. According to an exemplary embodiment, longer redundancy may be achieved. An emergency cooling operation may be provided if loss of building chilled water occurs. According to an exemplary embodiment, less air side pressure drop thru common fin stock may be obtained.

According to an exemplary embodiment a chilled water (CW)/CW dual circuit coil may be interlaced with common fin stock (see the diagram of FIG. 7 and FIGS. 8A-C). This coil configuration is unique and novel at least in the U.S. for use in a CRAH 300. This unique coil design may allow redundancy by allowing each circuit to be supplied from independent water sources. Normally a customer uses only one circuit at a time. The dual circuit coil design 700 according to an exemplary embodiment, may increase cooling capacity by better utilizing the full depth of the coil, allowing more coil fin surface area for optimal heat transfer. See FIGS. 5, 6, and 7, for drawings comparing a approach 600 to an interlaced dual circuit coil design 708 according to an exemplary embodiment of the invention. Additional fin surface area, according to an exemplary embodiment, may allow for parallel operation of two cooling circuits, nearly doubling the capacity of a chilled water coil because greater heat transfer is possible. The innovative dual circuit coil design 700 may also have a lower airside pressure drop through the common fin stock. Should a facility experience a loss in operation of the facility's chillers from, e.g., a power outage, this design may cool longer, while providing greater redundancy than other coil designs.

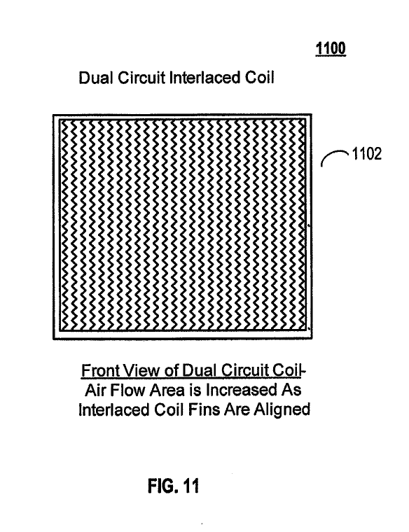

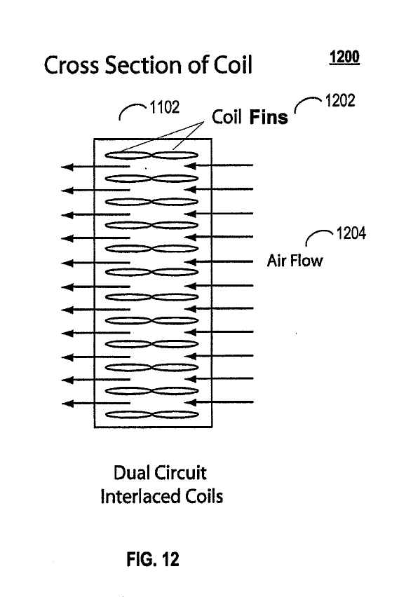

FIG. 11 depicts an exemplary dual circuit interlaced coil assembly 1100, showing the coil design 700 of FIG. 7 in expansive view. As illustrated, a dual circuit interlaced coil 1102 is provided, shown in frontal view. The air flow area is increased because the interlaced coil fins 1202 (described further with reference to FIG. 12) may be aligned in the dual circuit interlaced fashion.

FIG. 12 depicts a cross section of the dual circuit interlaced coil assembly 1100, showing the respective coil fins 1202. Also shown is how air flow 1204 is conducted between coil fins 1202 of the coils in the dual circuit interlaced coil assembly.

### Combination of Barrier Separated Fan CRAH and V-Frame Coil Exemplary Embodiment

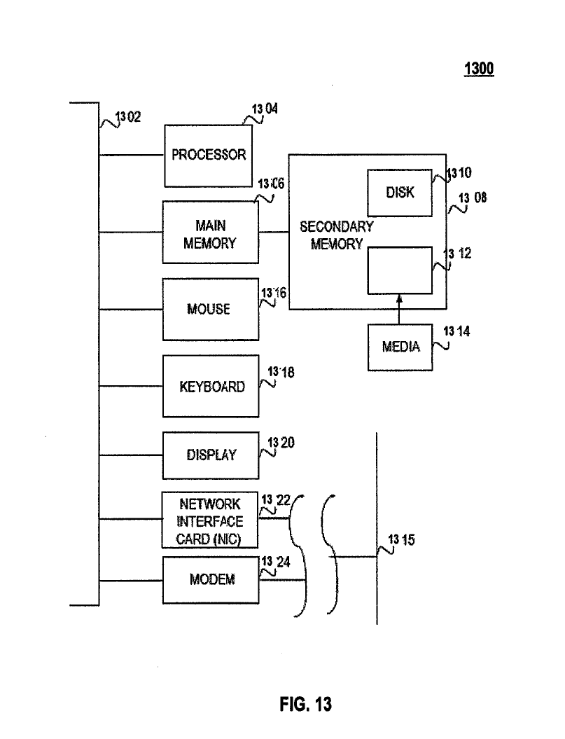

FIG. 13 depicts an exemplary control system 1300, which may include, according to an exemplary embodiment, a computer control system, a microcontroller controller control system, a solid state control system, or the like. CRAH 300 may make use of a control system 1300 to control operation of fans 302a, 302b, 302c housed in cabinet 306.

According to an exemplary embodiment, when the improved CRAH 300 cabinet design, including EC fan separation, is integrated with the V-frame coil design 500, air flow and static pressure may be further optimized, which in turn may allow the CRAH 300 to realize substantial energy consumption savings, yielding the lowest unit energy consumption in the industry to date. According to an exemplary embodiment, the barrier separated fan 302 CRAH 300 and V-frame coil 500 embodiments may further include the chilled water dual circuit coil design 700, which in an exemplary embodiment may be interlaced, providing further advantages and benefits over other systems.

Performance and use of an electronically commutated (EC) direct driven plug fan 202, 302 may be improved dramatically by the use of various embodiments of the present invention. Through extensive testing, the unique placement/separation method of the EC fans 302 in CRAH 300 and the reduced internal pressure drop by the use of a V-frame coil or alternatively V-frame dual circuit interlaced coil, has achieved a CRAH design 300 with the lowest per-unit energy consumption in the industry, using the least amount of floor space, allowing the EC Fan 302 to become a key component in modernizing computer room/datacenter design. The various exemplary embodiments provide substantial advantages in energy consumption and floor space efficiency as compared to alternative fan technologies and A-frame coil technology.

### Exemplary Embodiment of Computer Environment

FIG. 13 depicts an exemplary computer system that may be used in implementing various exemplary embodiments of the present invention. According to an exemplary embodiment, a computer system may be integrated as part of a air handling system as a control system for a fan, or fans, as well as above the raised floor, in a data center, where via an interface and/or sensors, the air handling system performance may be monitored via one or more computer systems. Specifically, FIG. 13 depicts an exemplary embodiment of a computer system 1300 that may be used in computing devices such as, e.g., but not limited to, a client and/or a server, etc., according to an exemplary embodiment of the present invention. FIG. 13 depicts an exemplary embodiment of a computer system that may be used as client device 1300, or a server device 1300, etc. The present invention (or any part(s) or function(s) thereof) may be implemented using hardware, software, firmware, or a combination thereof and may be implemented in one or more computer systems or other processing systems. In fact, in one exemplary embodiment, the invention may be directed toward one or more computer systems capable of carrying out the functionality described herein. An example of a computer system 1300 may be shown in FIG. 13, depicting an exemplary embodiment of a block diagram of an exemplary computer system useful for implementing the present invention. Specifically, FIG. 13 illustrates an example computer 1300, which in an exemplary embodiment may be, e.g., (but not limited to) a personal computer (PC) system running an operating system such as, e.g., (but not limited to) MICROSOFT® WINDOWS® NT/ 98/ 2000/ XP/ CE/ ME /VISTA/ etc. available from MICROSOFT® Corporation of Redmond, Wash., U.S.A. However, the invention may not be limited to these platforms. Instead, the invention may be implemented on any appropriate computer system running any appropriate operating system. In one exemplary embodiment, the present invention may be implemented on a computer system operating as discussed herein. An exemplary computer system, computer 1300 may be shown in FIG. 13. Other components of the invention, such as, e.g., (but not limited to) a computing device, a communications device, mobile phone, a telephony device, a telephone, a personal digital assistant (PDA), a personal computer (PC), a handheld PC, an interactive television (iTV), a digital video recorder (DVD), client workstations, thin clients, thick clients, proxy servers, network communication servers, remote access devices, client computers, server computers, routers, web servers, data, media, audio, video, telephony or streaming technology servers, etc., may also be implemented using a computer such as, e.g., or not limited to, that shown in FIG. 13. Services may be provided on demand using, e.g., but not limited to, an interactive television (iTV), a video on demand system (VOD), and via a digital video recorder (DVR), or other on demand viewing system.

The computer system 1300 may include one or more processors, such as, e.g., but not limited to, processor(s) 1304. The processor(s) 1304 may be connected to a communication infrastructure 1306 (e.g., but not limited to, a communications bus, cross-over bar, or network, etc.). Various exemplary software embodiments may be described in terms of this exemplary computer system. After reading this description, it may become apparent to a person skilled in the relevant art(s) how to implement the invention using other computer systems and/or architectures.

Computer system 1300 may include a display interface 1302 that may forward, e.g., but not limited to, graphics, text, and other data, etc., from the communication infrastructure 1306 (or from a frame buffer, etc., not shown) for display on the display unit 1330. In an exemplary embodiment of the present invention, a dashboard user interface may be provided for user interactive access to output and to provide responses to prompts/alerts/notifications, and to receive recommendations, which may be delivered in realtime, to, e.g., health care providers, such as a surgeon while in surgery. According to one exemplary embodiment, the interface may allow for input output using any of various convention interface devices such as, e.g., a stylus, a pen, a key, a mouse, a voice-recognition and voice interface, graphical buttons, audio and/or visual output.

The computer system 1300 may also include, e.g., but may not be limited to, a main memory 1308, random access memory (RAM), and a secondary memory 1310, etc. The secondary memory 1310 may include, for example, (but not limited to) a hard disk drive 1312 and/or a removable storage drive 1314, representing a floppy diskette drive, a magnetic tape drive, an optical disk drive, a compact disk drive CD-ROM, etc. The removable storage drive 1314 may, e.g., but not limited to, read from and/or write to a removable storage unit 1318 in a conventional manner. Removable storage unit 1318, also called a program storage device or a computer program product, may represent, e.g., but not limited to, a floppy disk, magnetic tape, optical disk, compact disk, etc. which may be read from and written to by removable storage drive 1314. As may be appreciated, the removable storage unit 1318 may include a computer usable storage medium having stored therein computer software and/or data. In some embodiments, a “machine-accessible medium” may refer to any storage device used for storing data accessible by a computer. Examples of a machine-accessible medium may include, e.g., but not limited to: a magnetic hard disk; a floppy disk; an optical disk, like a compact disk read-only memory (CD-ROM) or a digital versatile disk (DVD); a magnetic tape; and a memory chip, etc.

In alternative exemplary embodiments, secondary memory 1310 may include other similar devices for allowing computer programs or other instructions to be loaded into computer system 1300. Such devices may include, for example, a removable storage unit 1322 and an interface 1320. Examples of such may include a program cartridge and cartridge interface (such as, e.g., but not limited to, those found in video game devices), a removable memory chip (such as, e.g., but not limited to, an erasable programmable read only memory (EPROM), or programmable read only memory (PROM) and associated socket, and other removable storage units 1322 and interfaces 1320, which may allow software and data to be transferred from the removable storage unit 1322 to computer system 1300.

Computer 1300 may also include an input device 1316 such as, e.g., (but not limited to) a mouse or other pointing device such as, e.g., or not limited to, a digitizer, and a keyboard or other data entry device (not shown), and others such as, e.g., voice recognition, etc.

Computer 1300 may also include output devices, such as, e.g., (but not limited to) display 1330, and display interface 1302. Computer 1300 may include input/output (I/O) devices such as, e.g., (but not limited to) communications interface 1324, cable 1328 and communications path 1326, etc. These devices may include, e.g., but not limited to, a network interface card, and modems (neither may be labeled). Communications interface 1324 may allow software and data to be transferred between computer system 1300 and external devices.

In this document, the terms “computer program medium” and “computer readable medium” may be used to generally refer to media such as, e.g., but not limited to removable storage drive 1314, a hard disk installed in hard disk drive 1312, and signals 1328, etc. These computer program products may provide software to computer system 1300. The invention may be directed to such computer program products.

References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic. Further, repeated use of the phrase “in one embodiment,” or “in an exemplary embodiment,” do not necessarily refer to the same embodiment, although they may.

In the following description and claims, the terms “coupled” and “connected,” along with their derivatives, may be used. It should be understood that these terms may be not intended as synonyms for each other. Rather, in particular embodiments, “connected” may be used to indicate that two or more elements may be in direct physical or electrical contact with each other. “Coupled” may mean that two or more elements may be in direct physical or electrical contact. However, “coupled” may also mean that two or more elements may be not in direct contact with each other, but yet still co-operate or interact with each other.

An algorithm may be here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it may be appreciated that throughout the specification discussions utilizing terms such as, e.g., or not limited to, “processing,” “computing,” “calculating,” “determining,” or the like, refer to the action and/or processes of a computer or computing system, or similar electronic computing device, that manipulate and/or transform data represented as physical, such as, e.g., or not limited to, electronic, quantities within the computing system's registers and/or memories into other data similarly represented as physical quantities within the computing system's memories, registers or other such information storage, transmission or display devices.

In a similar manner, the term “processor” may refer to any device or portion of a device that processes electronic data from registers and/or memory to transform that electronic data into other electronic data that may be stored in registers and/or memory. As will be apparent to those skilled in the art, a “processor” may also include, e.g., but not limited to, a microcontroller, an application specific integrated circuit (ASIC), a programmable gate array (PGA), and/or a field programmable gate array (FPGA), etc. A “computing platform” may include one or more processors.

Embodiments of the present invention may include apparatuses for performing the operations herein. An apparatus may be specially constructed for the desired purposes, or it may include a general purpose device selectively activated or reconfigured by a program stored in the device.

In yet another exemplary embodiment, the invention may be implemented using a combination of any of, e.g., but not limited to, hardware, firmware and software, etc.

### Exemplary Embodiment of Under Floor Mounted Fans

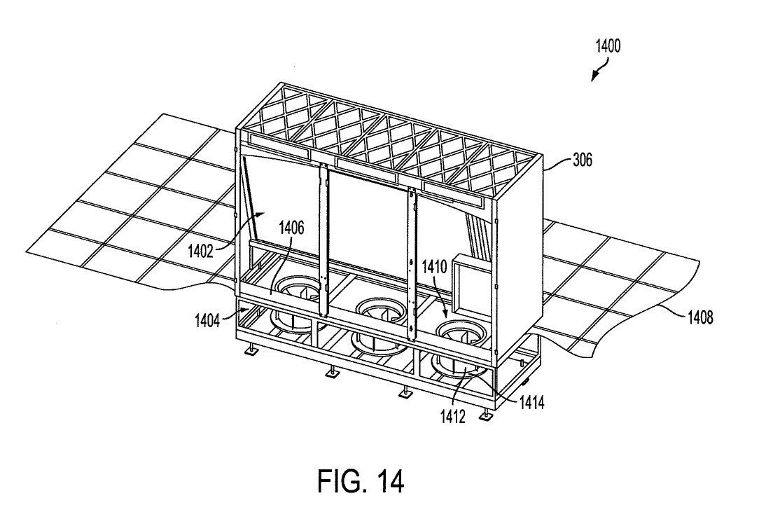

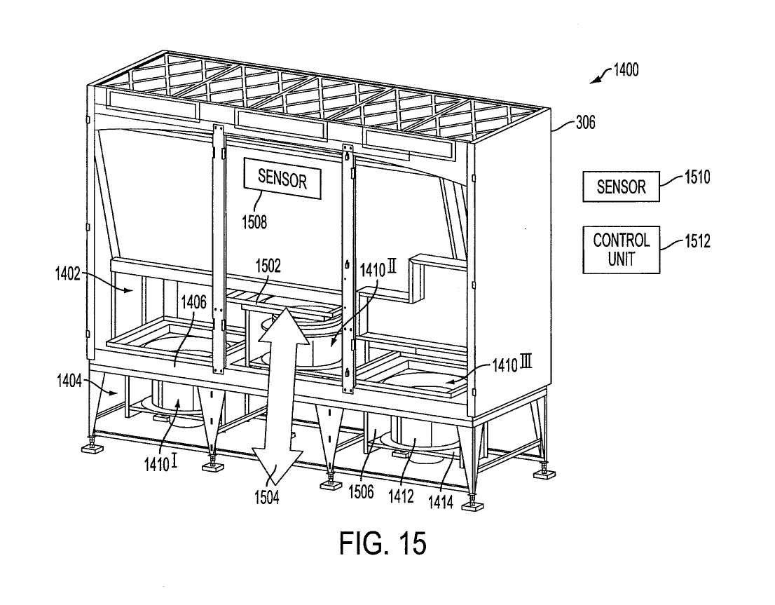

FIG. 14 depicts an exemplary embodiment of an air handling unit (or CRAH) for a computer room having a floor. The air handling unit 1400 can include a cabinet 306 having an upper chamber 1402 and a lower chamber 1404 separated, for example, by a partition 1406, which may be a horizontal partition or other similar structure. The lower chamber 1404 can be positioned in an air plenum located under the floor 1408. In an exemplary embodiment, a cooling device (not shown) can be located in the upper chamber 1402. A first fan assembly 1410 can be located in the cabinet 306. According to an exemplary embodiment, the first fan assembly 1410 can include a fan 1412 and a mounting device 1414 coupling the fan 1412 to the cabinet 306. The first fan assembly 1410 can be moveable along a first axis 1504 (see FIG. 15), e.g., a vertical axis, between the upper chamber 1402 and the lower chamber 1404. However, other configurations are possible.

In one exemplary embodiment, the cooling device may include a cooling coil (see the exemplary embodiments depicted in FIGS. 4-12). However, other conventional types of cooling devices can alternatively be used, such as, for example plate, shell-and-tube and/or plate-fin heat exchangers. The air handling unit may further include air filters.

According to an exemplary embodiment, the fans 1412 in the fan assemblies 1410 can include electronically commutated (EC) fans which operate, for example, when positioned in the air plenum located under the floor 1408. According to an exemplary embodiment, with the EC fans mounted in this position, the EC fans may not pressurize the lower chamber 1404 of the air handling unit 1400. Rather, the EC fans may directly discharge the air into the space or plenum below the raised floor 1408 resulting in increased efficiency (see FIG. 15). For example, the EC fans may create more airflow (cfm) and/or equal airflow (cfm) with less fan energy consumption.

FIG. 15 depicts an exemplary embodiment further including a lifting device 1502 biasing the fan assembly 1410 toward the upper chamber 1402. The lifting device 1502 can enable movement of the fan assembly 1410 along a first axis 1504 between the lower chamber 1404 located beneath the floor 1408 (see fan assemblies 1410^{I} and 1410^{III} shown in FIG. 15) and the upper chamber 1402 above the floor 1408 (see fan assembly 1410^{II}). This configuration can enable service, removal and/or replacement of any individual fan 1412 from the upper chamber 1402 of the air handling unit 1400.

In an exemplary embodiment, the lifting device 1502 may be, for example, but not limited to, a gas shock, a coil spring and/or an elastomer, etc. The lifting device 1502, or elastic member, can bias the fans 1412 toward the upper chamber 1402 along the first axis 1504. The lifting device 1502 can thus reduce the amount of effort required to raise the fans 1412 from below the raised floor 1408, for example, when desiring to service them from the front of the unit above the floor 1408. In order to lower the fans 1412 from the raised position in the upper chamber 1402, the operator can push the fan assembly 1410 downward, for example pressing, against the lifting device 1502 toward the lowered position in the lower chamber 1404. Other lifting devices, including mechanical and electromechanical devices, may be used as well.

In an exemplary embodiment, the air handling unit 1400 can further include a locking device (not shown) to lock the fan assembly 1410 in the lower chamber 1404. Generally, the locking device may include a member moveable between a first position where it locks the fan assembly 1410 in the lower chamber 1404 and a second position in which the locking device releases the fan assembly 1410. For example, the locking device can include, for example, but not limited to, a screw, a cam, a bracket or a quarter-turn screw, etc. A similar locking device, or other fastener, can also be provided to secure each fan assembly 1410 in the upper chamber 1402 of the cabinet 306.

According to an exemplary embodiment, the air handling unit 1400 further includes, for example, but not limited to, a track and/or rollers (not shown) coupling the mounting device 1414 of the fan assembly 1410 to the cabinet 306, where the fan assembly 1410 is moveable along the first axis 1504 on, for example, but not limited to, the track, bearings and/or rollers, etc. between the upper chamber 1402 and the lower chamber 1404. This exemplary configuration can permit the fan assembly 1410 to move between the upper chamber 1402 and the lower chamber 1404 without substantial disassembly, or any at all.

According to an exemplary embodiment, the air handling unit 1400 can further include at least a second fan 1412 and a second mounting device 1414. In this exemplary embodiment, the air handling unit 1400 can further include a separation barrier located between the first and second fans 1412 to separate the first and second fans 1412 into different fan compartments. The separation barrier may be coupled to the lower chamber 1404 of the cabinet 306 (see reference characters 304a and 304b of FIG. 3) or may be coupled to the first and/or second fan assemblies 1410 (as shown by reference character 1506 in FIG. 15). Further details relating to the structure and function of the separation barriers can be found in paragraphs 00061-00062 and 00067-00073.

The first and second fans 1412 can be independently moveable along the first axis 1504 from one another.

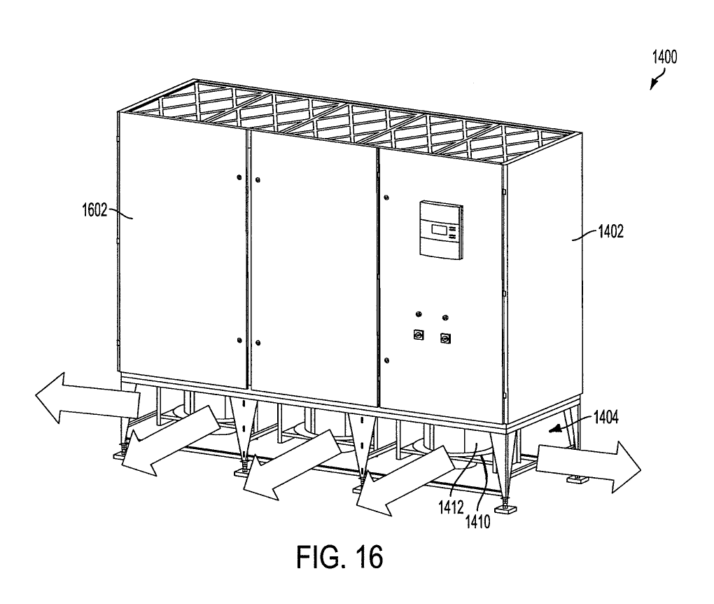

FIG. 16 is an exemplary embodiment depicting an air handling unit 1400 further including a front panel 1602 located on the cabinet 306. Air movement from the air handling unit 1400 into the air plenum under the floor 1408 is illustrated by the exemplary arrows in FIG. 16. Further, in one exemplary embodiment, a control device and/or display device may be included on the front panel 1602 of the cabinet 306 to monitor the operation of the air handling unit 1400.

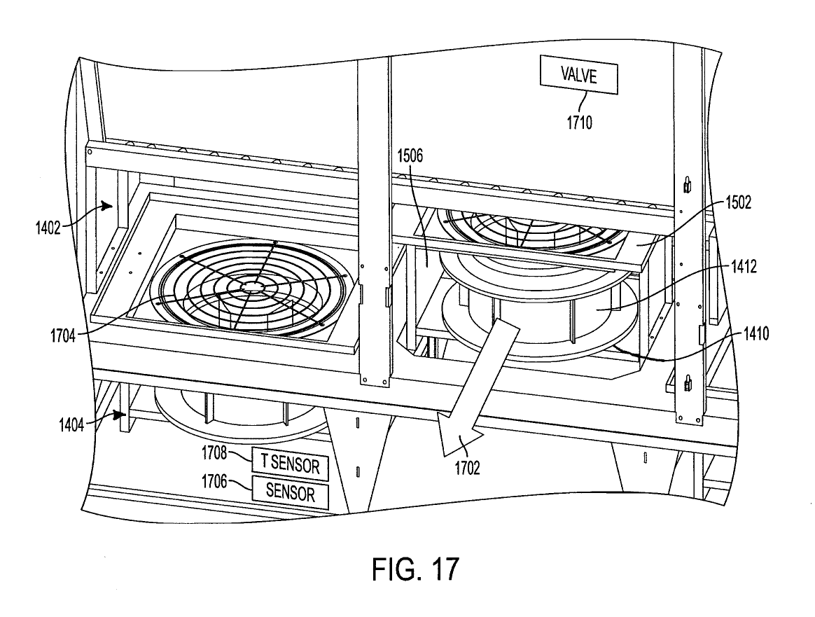

FIG. 17 depicts an exemplary embodiment, where the fan assembly 1410 is located in the upper chamber 1402, the first fan assembly 1410 may be moveable through the front panel 1602 along a second axis 1702 that is substantially transverse to the first axis 1504.

In one embodiment, the fan assembly 1410 is moveable along the second axis 1702 on, for example, but not limited to, a track and/or rollers, etc. (not shown). Thus, the fan assembly 1410 can slide or roll out of the upper chamber 1402 of the cabinet 306 for service, removal and/or repair. Additionally or alternatively, the air handling unit 306 can be shipped with the fan 1412 raised in the upper chamber 1402, to better protect the fan 1412 from damage.

In a further exemplary embodiment, safety guards 1704 can be provided on the inlet, outlet, and/or around the sides of each fan.

### Exemplary Embodiment of Cooling System with Step-Up

The cooling requirements for computer rooms, data centers and network/server rooms continue to grow as today's blade servers, data storage devices, and networking equipment increase in power and utility. Whereas in the past, computer room actual heat loads were approximately 1-3 kW, more recently racks may be loaded to 8, 10, or even 20 kW. To achieve the heat transfer rates required to remove such high amounts of sensible heat, the exemplary embodiments of the present invention can present a scaleable and reliable source of conditioned air to the IT equipment's cooling inlet(s). This can be accomplished, for example, by properly designing the cool air supply system to ensure that the server, despite its current demand, receives a sufficient air volumetric flow rate to remove the heat produced inside the server racks. According to an exemplary embodiment, a system can be designed based on the ability to maintain supply air temperatures inside the cabinet 306 while increasing air volumetric flow rates.

Conventional server fans may have variable speed fans that “step up” their fan speed as the internal equipment temperature increases. Typically, as the fan speed increases, initially the volumetric flow rate may increase as the fan does more real work. Without adjusting the flow available to the server fan, the pressure at the inlet of the server fans may begin to drop. This decrease in inlet pressure may limit the fans ability to move air and/or to meet the cooling needs of the server.

According to an exemplary embodiment, the air handling unit 1400 (or CRAH) can provide a greater volumetric flow rate to the server fans, when needed.

An exemplary embodiment of the air handling unit 1400 can include a pressure sensor 1508 that may monitor and report on rack interior pressure. A control unit 1512 can compare those values to the pressure detected exterior to the cabinet 306 by sensor 1510. When the servers' temperatures increase and the server fans' rotational speed increases, the pressure inside the cabinet 306 typically begins to drop. This pressure decrease can be reported back to the control unit 1512, which can generate a signal that increases the speed of fans 1412 to meet the increased air flow requirements of the IT equipment. An example, of the above-described exemplary embodiment may be the “Tower of Cool” manufactured by Wright Line of Worcester, Mass. which is currently available in 10, 16, and 22 kW models. The Tower of Cool may utilize supply and discharge air plenums, each equipped with a variable speed fan bank that is controlled by an Active Thermal Management System (ATMS).

For example, a first sensor 1508 can detect air pressure in the cabinet 306, and a second sensor 1510 can detect air pressure outside the cabinet 306. A control unit 1512 can increase the rotational speed of the fan 1412 when the air pressure in the cabinet 306 is lower than the air pressure outside the cabinet 306. Additionally or alternatively, the control unit 1512 can decrease the rotational speed of the fan 1412 when the air pressure in the cabinet 306 is higher than the air pressure outside the cabinet 306. However, other configurations are possible.

According to an exemplary embodiment, the air handling unit 1400 can include a sensor 1706 that detects air pressure in the air plenum located under the floor 1408. The control unit 1512 can compare the air pressure in the air plenum to a pre-determined set point pressure, and can increase or decrease the speed of the fan to match the air pressure in the air plenum to the pre-determined set point pressure. For example, the air handling unit 1400 can be adapted to serve a changing air flow requirement while maintaining a constant supply temperature. The air handling unit 1400 can be equipped with electronically commutated fans controlled by the control unit 1512. The sensor(s) 1706 under the plenum can include highly sensitive, professionally calibrated, static pressure sensors. These sensors 1706 can report the under floor pressure to the control unit 1512 and increase or decrease fan rotational speed to bring the under floor pressure back to a set point pressure.

According to an exemplary embodiment, the cooling device may include a cooling coil (see exemplary embodiments depicted in FIGS. 4-12). Further, the air handling unit 1400 may include a chilled water control valve 1710 that provides chilled water to the coil, and/or an air temperature sensor 1708 located in the air plenum located under the floor 1408. The control unit 1512 may control or regulate the chilled water control valve 1710 depending on the air temperature detected by the air temperature sensor 1708 to maintain a constant air temperature. For example, if the air temperature detected by the air temperature sensor 1708 is higher than desired, the control unit 1512 may increase the flow of chilled water through the chilled water control valve 1710 to introduce cooler air into the air plenum. If the air temperature detected by the air temperature sensor 1708 is lower than desired, the control unit 1512 may decrease the flow of chilled water through the chilled water control valve 1710 to introduce warmer air into the air plenum. Further to above, the air handling unit 1400 may maintain constant air supply temperature by modulation of the chilled water control valve 1710, which can in turn receive its control signal from the control unit 1512.

### EXEMPLARY DEFINITIONS

“Air Change per Hour” (ACH)—The number of times per hour that the volume of a specific room or building is supplied or removed from that space by mechanical and natural ventilation.

“Air handler, or air handling unit” (AHU)—Central unit may include a blower, heating and cooling elements, filter racks or chamber, dampers, humidifier, and other central equipment in direct contact with the airflow. The air handler typically does not include the ductwork through the building.

“British thermal unit” (BTU)—Any of several units of energy (heat) in the HVAC industry, each slightly more than 1 kilojoule (kJ). One BTU is the energy required to raise one pound of water one degree Fahrenheit, but the many different types of BTU are based on different interpretations of this “definition”. In the United States the power of HVAC systems (the rate of cooling and dehumidifying or heating) is sometimes expressed in BTU/hour instead of watts.

“Chiller”—A device that removes heat from a liquid via a vapor-compression or absorption refrigeration cycle. This cooled liquid flows through pipes in a building and passes through coils in air handlers, fan-coil units, or other systems, cooling and usually dehumidifying the air in the building. Exemplary chillers may include two types; air-cooled or water-cooled. Air-cooled chillers are usually outside and consist of condenser coils cooled by fan-driven air. Water-cooled chillers are usually inside a building, and heat from these chillers is carried by recirculating water to outdoor cooling towers.

“Controller”—A device that controls the operation of part or all of a system. It may simply turn a device on and off, or it may more subtly modulate burners, compressors, pumps, valves, fans, dampers, and the like. Most controllers are automatic but have user input such as temperature set points, e.g. a thermostat. Controls may be analog, or digital, or pneumatic, or a combination of these.

“Fan-coil unit” (FCU)—A small terminal unit that may include a blower and a heating and/or cooling coil (heat exchanger), as is often used in hotels, condominiums, or apartments.

“Condenser”—A component in the basic refrigeration cycle that may eject or remove heat from a system. The condenser is the hot side of an air conditioner or heat pump. Condensers are heat exchangers, and can transfer heat to air or to an intermediate fluid (such as water or an aqueous solution of ethylene glycol) to carry heat to a distant sink, such as ground (earth sink), a body of water, or air (as with cooling towers).

“Computer room air handler” (CRAH)—A CRAH may include a vertical, floor mounted air conditioner, which may be used to condition air for a computer room and/or data center, which may have a raised floor.

“Constant air volume” (CAV)—A system designed to provide a constant air volume per unit time. This term is applied to HVAC systems that may have variable supply-air temperature but constant air flow rates. Most residential forced-air systems are small CAV systems with on/off control.

“Damper”—A plate or gate placed in a duct to control air flow by introducing a constriction in the duct.

“Electronically Commutated Fan” (EC) may refer to an exemplary fan including an electronically commutated permanent magnet direct current (DC) motor, according to an exemplary embodiment. EC motor technology, according to an exemplary embodiment, may be insensitive to voltage fluctuations, may run extremely quietly, and may have continuously adjustable speeds and may include reduced power consumption. In essence, according to an exemplary embodiment, the EC fan motor may include a direct current (DC) motor with shunt characteristics. The rotary motion of an exemplary motor may be achieved by supplying power via a switching device (i.e., a commutator). In other motors, the commutator may use brushes, having a much shorter and limited service life of only a few thousand hours. With an EC motor, according to an exemplary embodiment, commutation may be performed using solid state electronics and may therefore be inherently wear-free by design.

“Evaporator”—A component in the basic refrigeration cycle that may absorb or add heat to the system. Evaporators can be used to absorb heat from air (by reducing temperature and by removing water) or from a liquid. The evaporator is the cold side of an air conditioner or heat pump.

“Fresh air intake” (FAI)—An opening through which outside air is drawn into the building. This may be to replace air in the building that has been exhausted by the ventilation system, or to provide fresh air for combustion of fuel.

“Grille”—A facing across a duct opening, usually rectangular is shape, containing multiple parallel slots through which air may be delivered or withdrawn from a ventilated space.

“Heat load, heat loss, or heat gain”—Terms for the amount of heating (heat loss) or cooling (heat gain) needed to maintain desired temperatures and humidities in controlled air. Regardless of how well-insulated and sealed a building is, buildings gain heat from warm air or sunlight or lose heat to cold air and by radiation.

Engineers use a heat load calculation to determine HVAC needs of the space being cooled or heated.

“Louvers”—Blades, sometimes adjustable, placed in ducts or duct entries to control the volume of air flow. The term may also refer to blades in a rectangular frame placed in doors or walls to permit the movement of air.

“Makeup air unit” (MAU)—An air handler that may condition 100% outside air. MAUs are typically used in industrial or commercial settings, or in once-through (blower sections that only blow air one-way into the building), low flow (air handling systems that blow air at a low flow rate), or primary-secondary (air handling systems that may have an air handler or rooftop unit connected to an add-on makeup unit or hood) commercial HVAC systems.

“Standard Cubic Feet per Minute” (SCFM) is the volumetric flow rate of a gas corrected to “standardized” conditions of temperature, pressure and relative humidity, thus representing a precise mass flow rate. However, great care must be taken, as the “standard” conditions may vary between definitions and should therefore always be checked. Worldwide, the “standard” condition for pressure is variously defined as an absolute pressure of 101325 pascals, 1.0 bar (i.e., 100,000 pascals), 14.73 psia, or 14.696 psia and the “standard” temperature may be variously defined as 68° F., 0° C., 15° C., 20° C. or 25° C. The relative humidity (e.g., 36% or 0%) may also be included in some definitions of standard conditions. There is, in fact, no universally accepted set of standard conditions. Temperature variation is important. In Europe, the standard temperature is most commonly defined as 0° C. (but not always). In the United States, the standard temperature is most commonly defined as 60° F. or 70° F. (but again not always). A variation in standard temperature can result in a significant volumetric variation for the same mass flow rate. For example, a mass flow rate of 1000 kg/hr of air at 1 atmosphere of absolute pressure is 455 SCFM when defined at 0° C. (32° F.) but 481 SCFM when defined at 60° F. (15.56° C.}. In countries using the SI metric system of unit, the term Normal Cubic Metre (Nm³) is very often used to denote gas volumes at some normalized or standard condition. Again, as noted above, there is no universally accepted set of normalized or standard conditions.

“Static Pressure”—In fluid mechanics, and in particular in fluid statics, static pressure is the pressure exerted by a fluid at rest. Examples of situations where static pressure is involved are: The air pressure inside a latex balloon is the static pressure and so is the atmospheric pressure (neglecting the effect of wind). The hydrostatic pressure at the bottom of a dam is by definition the static pressure as is the pressure exerted on one's thumb when stopping the water flow in a garden hose. The pressure inside a ventilation duct is not the static pressure, unless the air inside the duct is still.

“Variable air volume” (VAV) system—An HVAC system that has a stable supply-air temperature, and varies the air flow rate to meet the temperature requirements. Compared to CAV systems, these systems waste less energy through unnecessarily-high fan speeds. Most new commercial buildings have VAV systems.

“Thermal zone”—A single or group of neighboring indoor spaces that the HVAC designer may expect will have similar thermal loads. Building codes may require zoning to save energy in commercial buildings. Zones are defined in the building to reduce the number of HVAC subsystems, and thus initial cost. For example, for perimeter offices, rather than one zone for each office, all offices facing west can be combined into one zone. Small residences typically may have only one conditioned thermal zone, plus unconditioned spaces such as unconditioned garages, attics, and crawlspaces, and unconditioned basements.

While various embodiments of the present invention have been described above, it should be understood that they have been presented by way of example only, and not limitation. Thus, the breadth and scope of the present invention should not be limited by any of the above-described exemplary embodiments, but should instead be defined only in accordance with the following claims and their equivalents.

What is claimed is:

1. An air handling unit for a computer room having a raised floor, comprising:
a cabinet having an upper chamber and a lower chamber separated by a partition, wherein the lower chamber is positioned in an air plenum located under the raised floor;
a cooling device located in the upper chamber; and
a first fan assembly comprising a first fan and a first mounting device coupling the first fan to the cabinet, wherein the first fan assembly is movable along a first axis between the upper and lower chambers.

2. The air handling unit of claim 1, wherein the cooling device comprises a cooling coil.

3. The air handling unit of claim 1, further comprising a first lifting device biasing the first fan assembly toward the upper chamber.

4. The air handling unit of claim 3, wherein the first lifting device comprises at least one of a gas shock, a coil spring or an elastomer.

5. The air handling unit of claim 3, further comprising a locking device to lock the first fan assembly in the lower chamber.

6. The air handling unit of claim 5, wherein the locking device comprises at least one of a screw, a cam, a bracket, or a quarter-turn screw.

7. The air handling unit of claim 1, further comprising at least one of a track or rollers coupling the first mounting device to the cabinet, wherein the first fan assembly is movable along the first axis on at least one of the track or rollers between the upper and lower chambers.

8. The air handling unit of claim 1, further comprising a front panel located on the cabinet, wherein when the first fan assembly is located in the upper chamber, the first fan assembly is moveable through the front panel along a second axis that is substantially transverse to the first axis.

9. The air handling unit of claim 8, wherein the first fan assembly is movable along the second axis on at least one of a track or rollers.

10. The air handling unit of claim 1, further comprising:
a second fan assembly including a second fan and a second mounting device; and
a first separation barrier located between the first and second fans to separate the first and second fans into different fan compartments.

11. The air handling unit of claim 10, wherein the first separation barrier is coupled to the lower chamber of the cabinet.

12. The air handling unit of claim 10, wherein the first separation barrier is coupled to at least one of the first or second fan assemblies.

13. The air handling unit of claim 10, wherein the first and second fans are independently moveable along the first axis.

14. An air handling unit for a computer room having a raised floor, comprising:
a cabinet having an upper chamber and a lower chamber separated by a partition, wherein the lower chamber is positioned in an air plenum located under the raised floor;
a cooling device located in the upper chamber;
a fan located in the lower chamber, wherein the fan distributes air into the under-floor air plenum;
a first sensor that detects air pressure in the cabinet;
a second sensor that detects air pressure outside the cabinet; and
a control unit that increases rotational speed of the fan when the air pressure in the cabinet is lower than the air pressure outside the cabinet.

15. The air handling unit of claim 14, wherein the second sensor detects air pressure in the air plenum located under the raised floor.

16. The air handling unit of claim 15, wherein the control unit compares the air pressure in the air plenum to a pre-determined set point pressure, and increases or decreases speed of the fan to match the air pressure in the air plenum to the pre-determined set point pressure.

17. The air handling unit of claim 14, wherein the cooling device comprises a coil.

18. The air handling unit of claim 17, further comprising:
a chilled water control valve that provides chilled water to the coil; and
an air temperature sensor located in the air plenum located under the raised floor;
wherein the control unit controls the chilled water control valve depending on the air temperature detected by the air temperature sensor to maintain a constant air temperature.

19. The air handling unit of claim 14, wherein the fan is movable between the upper chamber and the lower chamber.

20. The air handling unit of claim 14, further comprising:
a second fan located in the lower chamber; and
a first separation barrier located between the first and second fans to separate the first and second fans into different fan compartments.
